(19) United States
(12) Patent Application Publication
(10) Pub. No.: US 2026/0123454 A1
(43) Pub. Date: Apr. 30, 2026

(54) LEAD FRAME, SSD MODULE, AND SSD DEVICE

(71) Applicant: Shenzhen SanDiYiXin Electronic Co., Ltd, Shenzhen (CN)

(72) Inventor: Xiangbing Chen, Longgang District (CN)

(21) Appl. No.: 19/003,517

(22) Filed: Dec. 27, 2024

(30) Foreign Application Priority Data
Oct. 30, 2024 (CN) 202411531717.9

(51) Int. Cl. H01L 23/495; H01L 23/00; H01L 25/065; H01L 25/18; H10B 80/00; H10D 80/30

(52) U.S. Cl. CPC H10W 70/421; H10B 80/00; H10D 80/30; H10W 70/468; H10W 90/00; H10W 90/24; H10W 90/752; H10W 90/753; H10W 90/754; H10W 90/756

(57) ABSTRACT

A lead frame, an SSD module, and an SSD device. The lead frame includes: a first base island, configured to mount a storage control chip; a second base island, configured to mount a Flash; and a pin array, distributed around a periphery of the first base island.

### CROSS REFERENCE TO RELATED APPLICATIONS

The present application claims the priority of Chinese patent application No. 202411531717.9, filed on Oct. 30, 2024, and the entire contents of which are hereby incorporated by reference in its entirety.

### TECHNICAL FIELD

The present disclosure relates to the field of packaging technologies, and in particular to a lead frame, an SSD module, and an SSD device.

### BACKGROUND

NAND Flash (referred to as Flash) is currently the most popular storage medium and is widely applied in the manufacture of various types of storage products, such as a solid-state drive (SSD) device. The SSD device includes components such as a storage control chip, Flash, and PCB. The storage control chip contains firmware that runs internally to manage the Flash, so as to control the Flash to read and write data. The PCB is a base board that electrically connects the storage control chip to the Flash.

In the related art, the storage control chip and Flash are both independently packaged through a ball grid array (BGA) and are bonded together with peripheral components (such as resistors and capacitors) to the PCB, so as to manufacture the SSD device. However, the SSD devices manufactured by means of the above solution have the following defects:

The BGA packaging of the storage control chip and Flash is not cheap. In addition, since the storage control chip and Flash are individually packaged, the packaging cost of the SSD device is further increased. Both of these directly affect the profit margin of the SSD device manufacturer.

### SUMMARY OF THE DISCLOSURE

The purpose of the present disclosure is to overcome the deficiencies in the related art and provide a lead frame, an SSD module, and an SSD device, that can reduce the packaging cost of the SSD device.

In a first aspect, the present disclosure provides a lead frame, including:
a first base island, configured to mount a storage control chip;
a second base island, configured to mount a Flash; and
a pin array, distributed around a periphery of the first base island.

In some embodiments, the pin array includes a power pin, a signal pin, and a ground pin; the power pin connected to the Flash extends from an end of the lead frame to another end of the lead frame and is disposed between the first base island and the second base island.

In a second aspect, the present disclosure provides an SSD module, including: the storage control chip, the Flash, and the lead frame as above;
wherein the storage control chip is arranged on the first base island, and the Flash is arranged on the second base island; solder pads of the storage control chip, solder pads of the flash, and the pin array are wire bonded by means of bonding wires and packaged into a QFN package to form the SSD module.

In some embodiments, at least one of the solder pads of the storage control chip, which is wire bonded to the Flash, is located on a side of the power pin; at least one of the solder pads of the Flash, which is wire bonded to the storage control chip, is located on another side of the power pin.

In some embodiments, the storage control chip is arranged with a strobe module, and the strobe module is configured to adjust signal types of the solder pads of the storage control chip, enabling the signal types of the storage control chip to match signal types of the solder pads of the Flash to achieve direct wire bonding.

In some embodiments, the strobe module includes a control unit and a plurality of channel selection units; a control terminal of the control unit is connected to the plurality of channel selection units; each channel selection unit includes a multiplexer and a plurality of I/O channels, an input end of the multiplexer being connected to a corresponding I/O port of the storage control chip; the multiplexer is configured to receive a signal from the control unit, and a selection terminal of the multiplexer is caused to be connected to an end of one of the plurality of I/O channels; another end of each I/O channel is connected to a corresponding solder pad of the storage control chip.

In some embodiments, the Flash includes a plurality of Flashes; the plurality of Flashes are stacked and distributed in a staggered manner to form a stepped storage unit structure, and the solder pads, of a same type, of the plurality of Flashes are connected by bonding wires.

In some embodiments, both ends of the power pin are not covered by a colloid.

In a first aspect, the present disclosure provides an SSD device, including: a PCB, peripheral components, a housing, and the SSD module as above;
wherein the peripheral components and the SSD module are arranged together on the PCB, and the PCB is arranged in the housing to form the SSD device.

In some embodiments, the PCB is arranged with gold fingers.

The lead frame includes: a first base island, configured to mount a storage control chip; a second base island, configured to mount a Flash; and a pin array, distributed around a periphery of the first base island. Due to the arrangement of the first base island and the second base island, the lead frame can simultaneously integrate the storage control chip and the Flash. The lead frame can be packaged to manufacture an SSD module, and the storage control chip and the Flash are not required to be separately packaged and assembled into an SSD module, which reduces the manufacturing difficulty of the SSD module and effectively reduces the packaging cost of the SSD device.

Further, the pin array in the lead frame is distributed around the first base island, such that the SSD module can be manufactured using a QFN package. Compared with a BGA package, the QFN package can further reduce the packaging cost of the SSD device and increase the profit margin of the SSD manufacturer.

### BRIEF DESCRIPTION OF THE DRAWINGS

In order to more clearly illustrate the technical solution of the embodiments of the present disclosure, the following is a brief description of the drawings for use in the embodiments. It should be understood that the following drawings only show certain embodiments of the present disclosure, and therefore should not be regarded as a limitation of the scope. For those skilled in the art, other relevant drawings can be obtained without the expenditure of creative labor based on these drawings.

FIG. 1 is a structural schematic view of a lead frame according to some embodiments of the present disclosure.

FIG. 2 is a structural schematic view of an SSD module (unpackaged) according to some embodiments of the present disclosure.

FIG. 3 is a structural schematic view of an SSD module (packaged) according to some embodiments of the present disclosure.

FIG. 4 is a structural schematic view of an SSD device according to some embodiments of the present disclosure.

FIG. 5 is a connection schematic diagram of a storage control chip, a strobe module, and a Flash according to some embodiments of the present disclosure.

FIG. 6 is a structural schematic diagram of a channel selection unit (not yet Pad to Pad) according to some embodiments of the present disclosure.

FIG. 7 is a structural schematic diagram of a channel selection unit (already Pad to Pad) according to some embodiments of the present disclosure.

### DETAILED DESCRIPTION

In order to facilitate an understanding of the present disclosure, the following description of the present disclosure will be supplemented by the associated drawings. The drawings show some embodiments of the present disclosure. However, the present disclosure can be implemented in many different forms and is not limited to the embodiments described herein. Rather, these embodiments are provided to enable a more thorough understanding of the present disclosure.

It should be noted that when an element is described to be “fixed to” another element, it may be directly on the other element or there may be a centering element therebetween. When an element is described to be “connected to” another element, it may be directly connected to the other element or there may be a centering element therebetween. The terms “vertical”, “horizontal”, “left”, “right” and similar expressions in the description are for the purpose of illustration only and do not indicate the only implementation.

Unless otherwise defined, all technical and scientific terms used herein have the same meaning as commonly understood by those skilled in the art. The terms used herein in the description of the present disclosure are for the purpose of describing specific embodiments only and are not intended to limit the present disclosure. The term “and/or” as used herein includes any and all combinations of one or more of the listed items.

In the relevant art, the storage control chip and Flash are both independently packaged through a ball grid array (BGA) and are bonded together with peripheral components (such as resistors and capacitors) to the PCB, so as to manufacture the SSD device. However, the SSD devices manufactured by means of the above solution have the following defects: The BGA packaging of the storage control chip and Flash is not cheap. In addition, since the storage control chip and Flash are individually packaged, the packaging cost of the SSD device is further increased. Both of these directly affect the profit margin of the SSD device manufacturer.

Therefore, in order to solve the above technical problems, the present disclosure provides a lead frame that can reduce the packaging cost of the SSD device.

The technical solutions of the present disclosure are described in detail below in conjunction with the accompanying drawings.

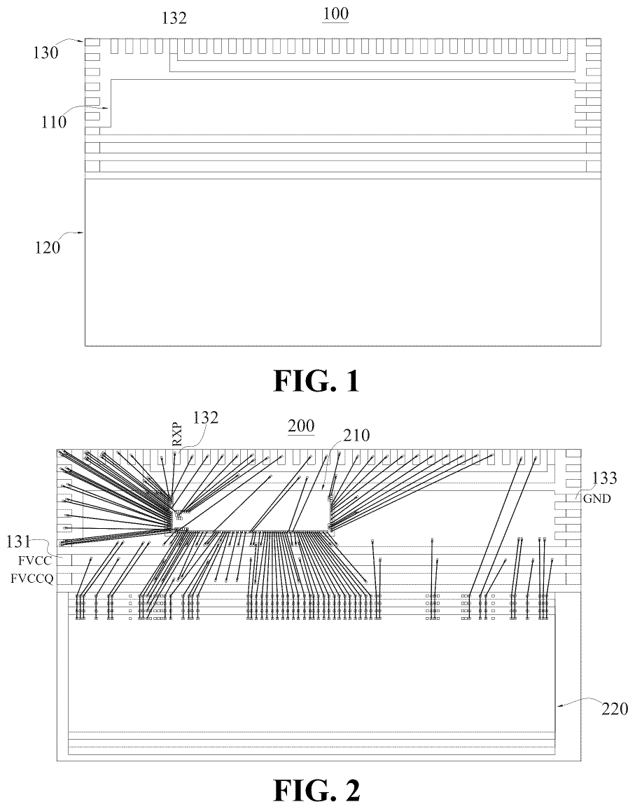

FIG. 1 is a structural schematic view of a lead frame according to some embodiments of the present disclosure.

Referring to FIGS. 1 and 2, the lead frame 100 includes: a first base island 110, a second base island 120, and a pin array 130. It should be noted that the lead frame 100 serves as a chip carrier of an integrated circuit, which is a key structural component that forms an electrical circuit by means of a bonding material (such as gold wire, aluminum wire, or copper wire) to achieve an electrical connection between an internal circuit lead of a chip and an external lead, i.e., as a bridge to connect with external leads. In the present embodiments, the chip includes two types of chips: one is a storage control chip 210, and the other is a Flash 220 (which can also be a memory chip). When the storage control chip 210 is connected to the Flash 220, the storage control chip 210 can control the Flash 220 to complete data reading and writing by means of the firmware running internally.

The first base island 110 is configured to provide a mounting position for the storage control chip 210, and the storage control chip 210 is arranged in the first base island 110. In the present embodiments, a bottom of the first base island 110 is a large piece of metal-plated tin-copper skin that can conduct heat. When the storage control chip 210 is working, heat is inevitably generated, and the metal-plated tin-copper skin of the first base island 110 can transfer the heat to outside very well, thereby dissipating the heat from the storage control chip 210.

Similarly, the second base island 120 is configured to provide a mounting position for the Flash 220, and the Flash 220 is arranged in the second base island 120. In the present embodiments, a bottom of the second base island 120 is a large piece of metal-plated tin-copper skin that can conduct heat. The heat generated by the Flash 220 during operation is transferred to the outside through the metal-plated tin-copper skin of the second base island 120, thereby dissipating the heat from the Flash 220.

The pin array 130 serves as a solder pad of the lead frame 100 and is configured to connect with an external device. The pin array 130 is a common lead-out pin of the storage control chip 210 and the Flash 220. The external device can communicate with the storage control chip 210 and the Flash 220 through the pin array 130, so as to complete data transmission. In the present embodiments, the pin array 130 is distributed around the first base island 110.

In the technical solution of the present embodiments, due to the arrangement of the first base island 110 and the second base island 120, the lead frame 100 is enabled to simultaneously integrate two types of chips, i.e., the storage control chip 210 and the Flash 220. Therefore, the lead frame 100 can be packaged to directly manufacture an SSD module. The storage control chip 210 and the Flash 220 do not need to be separately packaged and assembled into an SSD module, which reduces the difficulty of manufacturing the SSD module and effectively reduces the packaging cost of the SSD device.

Furthermore, in some embodiments, the pin array 130 includes a power pin 131, a signal pin 132, and a ground pin 133; where the power pin 131 connected to the Flash 220 extends from an end of the lead frame 100 to another end of the lead frame 100 and is disposed between the first base island 110 and the second base island 120.

In the present embodiments, the pin array 130 can be mainly divided into three types: the power pin 131, the signal pin 132, and the ground pin 133. The power pin 131 is configured to output or input a voltage signal to supply power to the storage control chip 210 or the Flash 220. The signal pin 132 is configured to be connected to the external device and transmit or receive signals such as data, commands, and addresses. The ground pin 133 is a grounding pin of the storage control chip 210 and the Flash 220, and is configured to provide a common reference potential, improve circuit stability, and reduce external signal interference.

In addition, considering that the read and write performance and stability of the SSD device are important factors affecting the price, and that the Flash 220 is the main influencing factor, the stability of the power supply of the Flash 220 is particularly important. In the present embodiments, the power pin of the lead frame is optimally designed in terms of its design distribution and structure in the following two aspects.

(1) The power pin 131 connected to the Flash 220 extends from an end of the lead frame 100 to another end of the lead frame 100. Referring to FIG. 2, in this embodiment, the power pin 131 connected to the Flash 220 includes an FVCC power pin and an FVCCQ power pin. Both of these power pins supply power to the Flash 220. As can be seen in FIG. 2, the FVCC power pin and the FVCCQ power pin are in the shape of a long rectangular strip. Since the power pads of different models of the Flash 220 are distributed in different positions, the power pads of some models of the Flash 220 may be located on solder pads 1 to 3, or solder pad 1, 10, 22, 20, or 30. Due to the random distribution of the power pads, if the power pin of the lead frame 100 is not designed as a long rectangular strip, when the power pin is subjected to wire bonding, the bonding wire may be required to span the entire length of the lead frame to reach the power pin, i.e., the bonding wire will be too long, which greatly increases the difficulty of wire bonding the lead frame 100 and reduces the wire bonding yield. In the present embodiment, since the power pin extends from one end of the lead frame 100 to the other end, even if the power pad of the Flash 220 is randomly distributed, direct wire bonding (Pad to Pad) can still be achieved. For example, when the Flash 220 includes two power pads that are located at solder pads 1 and 30, both the power pads can be connected to the nearest power pin 131 for wire bonding, which effectively shortens the length of the bonding wire and improves the wire bonding yield.

(2) The flash 220 is one of the components that affects the stability of the SSD device, and the quality of the power supply output to the Flash 220 is particularly important. In the present embodiment, the length of the power pin 131 is greater than that of other types of pins, so as to improve its current carrying capacity, heat dissipation performance, filtering effect, electromagnetic compatibility, and power supply stability, thereby ensuring that Flash 220 can stably receive a stable and clean power supply signal.

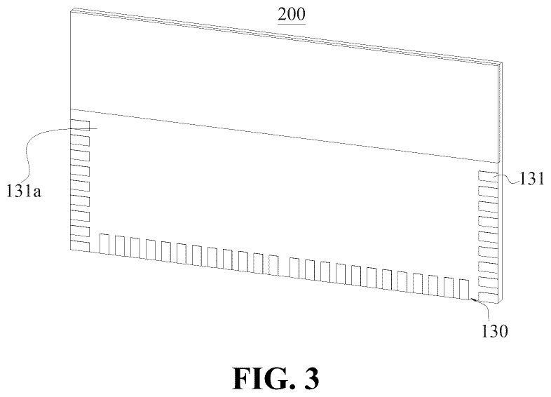

It should be noted that the number of pins on the SSD module 200 in FIGS. 2 and 3 is not the same. FIGS. 2 and 3 only serve as structural illustrations. In actual application, the number of pins on the unpackaged and packaged SSD module 200 may be the same or different. This is because multiple pins of the same type can be led out, and it is only necessary to connect these pins of the same type together before they are led out.

In addition, in FIG. 2, only the FVCC, FVCCQ, GND, and RXP pins are shown schematically, but the SSD module 200 may have many other types of pins. Due to word limit, the schematic description of the pins of the SSD module 200 cannot be exhaustive, which is related to the storage control chip, the flash, and the chip design. Common pins of the SSD module 200 include: ALE, CLE, CMD, DATA, CE, VCC, GND and other pin types.

FIG. 2 is a structural schematic view of an SSD module (unpackaged) according to some embodiments of the present disclosure.

Referring to FIGS. 2 and 3, the SSD module 200 includes: a storage control chip 210, a Flash 220, and the above lead frame 100.

It should be noted that the storage control chip 210 runs firmware related to the Flash 220 internally. The firmware is equivalent to the “brain” of the storage control chip 210, and can execute corresponding operations based on the instructions and data received by the storage control chip 210, for example, controlling the Flash 220 to complete data reading and writing. The Flash 220 is a data storage position of the SSD module 200. The lead frame 100 serves as a chip carrier for the integrated circuit and provides mounting positions for the storage control chip 210 and the Flash 220.

In the present embodiments, the storage control chip 210 is arranged on the first base island 110, and the Flash 220 is arranged on the second base island 120. Solder pads 211 of the storage control chip 210, solder pads 221 of the flash 220, and the pin array 130 are wire bonded by means of bonding wires and packaged into a QFN package to form the SSD module 200.

It should be noted that due to the arrangement of the first base island 110 and the second base island 120, the lead frame 100 can simultaneously integrate two types of chips, i.e., the storage control chip 210 and the Flash 220. Packaging the lead frame 100 can be directly manufactured into an SSD module 200, and the storage control chip 210 and Flash 220 are therefore not required to be separately packaged and assembled into an SSD module 200, which reduces the difficulty of manufacturing the SSD module 200 and can effectively reduce the packaging cost of the SSD device.

In addition, in the present embodiments, since the lead frame 100 is a single-layer frame, the cost will be lower compared to a lead frame with a double-layer or multi-layer frame.

Furthermore, the SSD module 200 of the present disclosure can simplify the production difficulty for SSD device manufacturers. Since the storage control chip 210 and the Flash 220 have been integrated in the same lead frame 100 and packaged, it is equivalent to that the SSD module 200 is packaged into a single chip with data storage function. When the SSD device manufacturer wants to use the SSD module 200 to process and produce an SSD device, the SSD module 200 can be directly matched with a PCB and peripheral components, which greatly facilitates manufacturing at the application end.

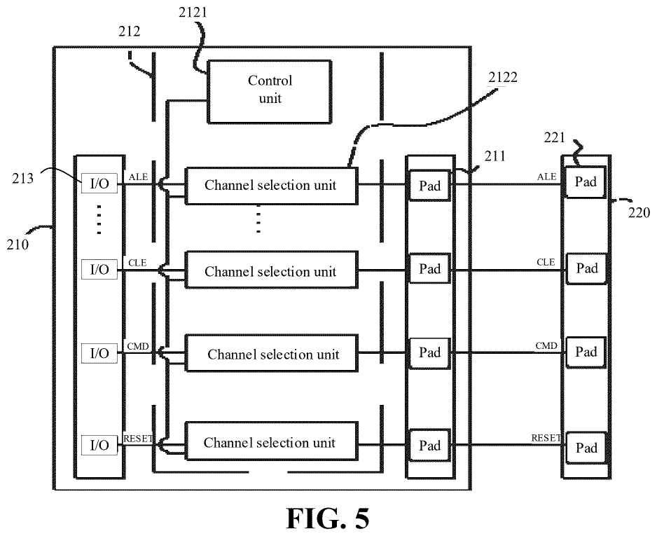

Referring to FIG. 5, in some embodiments, the solder pad 211 of the storage control chip 210, which is wire bonded to the Flash 220, is located on a side of the power pin 131; the solder pad 221 of the Flash 220, which is wire bonded to the storage control chip 210, is located on the other side of the power pin 131.

It should be noted that in order to maximize the wire bonding yield, the solder pads of the storage control chip 210 and the Flash 220, that are connected to each other, shall be opposite to each other in a one-to-one correspondence as much as possible, which is intended to shorten the length of the bonding wire, thereby increasing the wire bonding yield while also reducing production costs.

Referring to FIG. 5, in some embodiments, the storage control chip 210 is arranged with a strobe module 212, and the strobe module 212 is configured to adjust the signal type of the solder pad 211 of the storage control chip 210, such that the storage control chip 210 can match the signal type of the solder pad 221 of the Flash 220, thereby achieving the direct wire bonding.

In actual application, the distribution of the solder pads of Flash 220 will vary with the model of the Flash 220, but the model of the Flash 220 purchased by the SSD module manufacturer within a certain period of time cannot be fixed. If the distribution of the pad types of the storage control chip 210 does not correspond to the distribution of the pad types of the Flash 220 (i.e., the direct wire bonding cannot be achieved), cross wire bonding must be performed. For example, when the ALE of the storage control chip 210 is located on the solder pad 1 and the CLE is located on the solder pad 20, whereas the ALE of the Flash 220 is located on the solder pad 20 and the CLE is located on the solder pad 1, in order to realize the design where the ALE of the storage control chip 210 is connected to the ALE of the Flash 220, and the CLE of the storage control chip 210 is connected to the CLE of the Flash 220, direct wire bonding cannot be performed, and only cross wire bonding can be performed. Since wire bonding is a highly delicate operation, cross wire bonding will greatly increase the overall difficulty of wire bonding, and even if the wire is bonded, the two crossed bonding wires are very likely to make contact by mistake. Therefore, cross wire bonding should be avoided as much as possible when producing the SSD module 200.

In response thereto, according to the above situation, the storage control chip 220 of this embodiment is arranged with the strobe module 212 internally. The strobe module 212 is configured to adjust the signal type of the solder pad 211 of the storage control chip 210, such that the storage control chip 211 can match the signal type of the solder pad 221 of the Flash 220, thereby achieving direct wire bonding. Continuing with the above example, the ALE of the storage control chip 210 is located on the solder pad 1 and the CLE is located on the solder pad 20. After adjustment by the strobe module 212, the distribution of the solder pads of the storage control chip 210 changes as follows:

ALE, before adjustment: solder pad 1; after adjustment: solder pad 20.

CLE, before adjustment: solder pad 20; after adjustment: solder pad 1.

In this way, the solder pads 211 corresponding to ALE and CLE of the storage control chip 210 match with the solder pads 221 corresponding to ALE and CLE of the Flash 220, and thus the direct wire bonding can be achieved. The arrangement of the strobe module 212 can well cope with the above situation, improve the yield of wire bonding, and avoid cross-bonding.

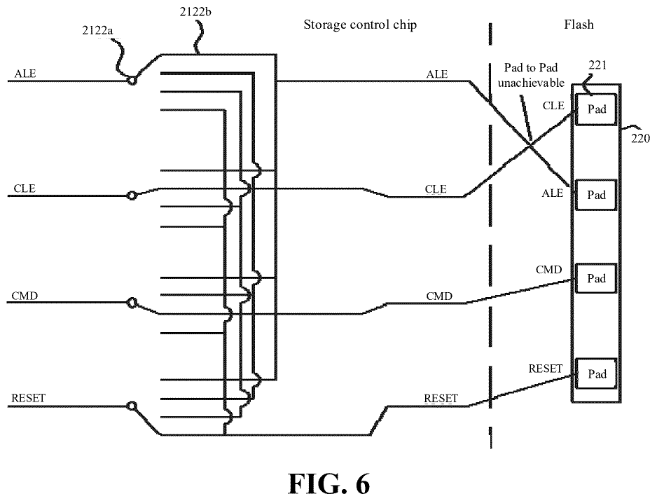

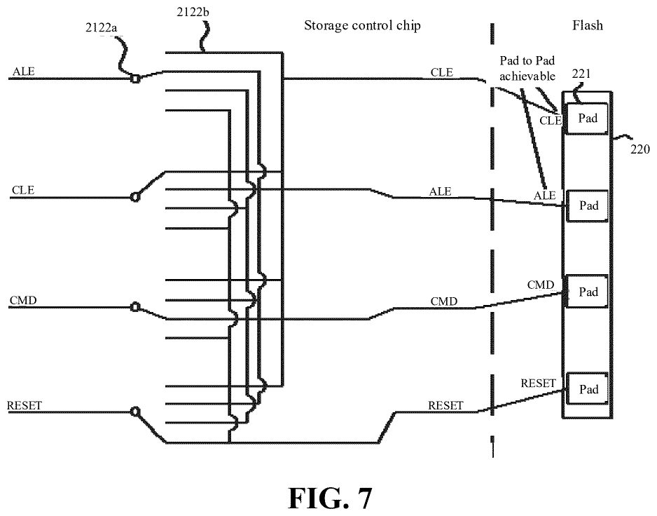

Further, referring to FIGS. 6 and 7, in some embodiments, the strobe module 212 includes a control unit 2121 and multiple channel selection units 2122. A control terminal of the control unit 2121 is connected to the multiple channel selection units 2122. Each channel selection unit 2122 includes a multiplexer 2122a and multiple I/O channels 2122b, an input end of the multiplexer 2122a being connected to a corresponding I/O port 213 of the storage control chip 210; the multiplexer 2122a is configured to receive a signal from the control unit 2121, such that a selection terminal of the multiplexer 2122a is connected to an end of one of the multiple I/O channels 2122b, and another end of each I/O channel 2122b is connected to a corresponding solder pad 212 of the storage control chip 210.

The storage control chip 210 shown in FIGS. 6 and 7 has four I/O ports: ALE, CLE, CMD, and Reset. According to the conventional internal wiring, the ALE port is connected to the solder pad 1, the CLE port is connected to the solder pad 2, the CMD port is connected to the solder pad 3, and the Reset port is connected to the solder pad 4. As for the Flash 220, the ALE port is connected to the solder pad 2, the CLE port is connected to the solder pad 1, the CMD port is connected to the solder pad 3, and the Reset port is connected to the solder pad 4. It can be seen that if the storage control chip 210 is to communicate normally with the Flash 220 communicate and interact normally, the signal types corresponding to the pad positions should be the same. According to the current distribution of the pad types of the storage control chip 210, it is impossible to achieve direct wire bonding, and there will be cross-over of the bonding wires for ALE and CLE. In this case, the control unit 2121 can control the corresponding channel selection unit 2122 for ALE and CLE, and the multiplexer 2122a can be controlled to select one of the I/O channels 2122b, thereby swapping the pad positions of the ALE and CLE ports. Each multiplexer 2122a corresponds to four I/O channels 2122b. The multiplexer 2122a corresponding to ALE is caused to select the second I/O channel 2122b to connect, and multiplexer 2122a corresponding to CLE is caused to select the first I/O channel 2122b to connect, while the other two ports remain unchanged. This achieves the swapping of the pad positions of ALE and CLE, such that the signal types of the pads of storage control chip 210 and the Flash 220 match each other, thereby achieving direct wire bonding (Pad to Pad).

The above example only serves to illustrate the principle. In actual application, the signal types of storage control chip 210 are diverse, but not limited to the four listed in the above example. The number of I/O channels 2122b should be consistent with the number of I/O ports of the storage control chip 210. For example, when the storage control chip 210 has 20 I/O port types, then each channel selection unit 2122 should have 20 I/O channels 2122b, such that the positions of the 20 I/O ports can be swapped.

Referring to FIG. 2, in some embodiments, multiple Flashes 220 are arranged, and the multiple Flashes 220 are stacked and distributed in a staggered manner, such that the stacked multiple Flashes 220 form a stepped storage unit structure, and the solder pads of the same type of the multiple Flashes 220 are connected by bonding wires.

It should be noted that in the present embodiments, the number of the Flashes 220 can be multiple. When the multiple Flashes 220 are integrated in the same lead frame 100, the Flashes 220 are stacked and staggered to form a stepped storage unit structure, and the staggered distribution can expose the solder pads of the Flashes 220 for wire bonding through the bonding wires, and the solder pads of the same type can be connected through the bonding wires. Integrating multiple Flash 220 can increase the capacity of the SSD module 200.

Referring to FIG. 3, in some embodiments, both ends of the power pin 131 are not covered by a colloid 131a. It should be noted that after the lead frame 100 is installed with the storage control chip 210 and the Flash 220, it can be packaged. In this embodiment, the SSD module 200 is packaged in a QFN package. The power pin 131 of the lead frame 100 is packaged. Since the power pin 131 is a long rectangular strip, when the SSD module 200 is installed, the power pin 131 is required to be exposed at both ends for the chip to be attached. Therefore, a part of the power pin 131 other than the two ends can be covered with the colloid 131a, which may protect the power pin 131.

In the technical solution of the present embodiments, the first base island 110, the second base island 120, and the pin array 130 are distributed around the periphery of the first base island 110, such that the SSD module 200 can be packaged in a QFN package, which is less expensive than a BGA package. Conventionally, the SSD module on the market is packaged separately with the storage control chip and the Flash, which is expensive (especially when multiple Flashes are required, the packaging cost will increase significantly). In the present disclosure, the storage control chip 210 and the Flash 220 are integrated into the lead frame 100 and then packaged together, which only requires a one-time package cost, without the need of multi-times time cost. In addition, the storage control chip 210 has an I/O customization function, and the solder pad definition of the storage control chip 210 can be customized to match the solder pad definition of the Flash 220, thereby achieving direct wire bonding, such that the storage control chip 210 can be compatible with more models of the Flash 220.

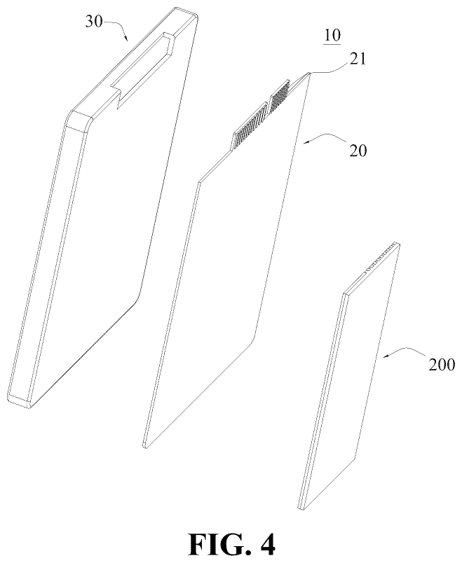

FIG. 4 is a structural schematic view of an SSD device according to some embodiments of the present disclosure.

Referring to FIG. 4, the SSD device 10 includes: a PCB 20, peripheral components (not shown), a housing 30, and the SSD module 200 as described above. The peripheral components and the SSD module 200 are arranged together on the PCB 20, and the PCB 20 is arranged in the housing 30 to form the SSD device 10.

It should be noted that the functional features and functional effect descriptions of the SSD module 200, lead frame 100, and storage control chip 210 are described in the preceding content and will not be repeated here.

Referring to FIG. 4, in some embodiments, the PCB 20 is arranged with gold fingers 21, and the gold fingers 21 are an interface of the SSD device. The external device can communicate with the SSD device 10 through the gold fingers 21.

In the technical solution of the present embodiments, since the SSD module 200 has already been packaged as a whole, the SSD device manufacturer only needs to directly mount the SSD module 200 and the peripheral components together on the PCB 20 to produce the SSD device 10. In this way, the production process is simple, without excessive cumbersome steps, which greatly improves the production efficiency of the SSD device 10.

The above is the description of some embodiments of the present disclosure. The above description is exemplary and not exhaustive, and is not limited to the disclosed embodiments. Many modifications and changes are obvious to those skilled in the art without departing from the scope and spirit of the described embodiments. The choice of terminology used herein is intended to best explain the principles of the various embodiments, their practical application, or their improvement over prior art in the market, or to enable those skilled in the art to understand the various embodiments disclosed herein.

What is claimed is:

1. A lead frame, comprising:
a first base island, configured to mount a storage control chip;
a second base island, configured to mount a Flash; and
a pin array, distributed around a periphery of the first base island.

2. The lead frame according to claim 1, wherein the pin array comprises a power pin, a signal pin, and a ground pin; the power pin connected to the Flash extends from an end of the lead frame to another end of the lead frame and is disposed between the first base island and the second base island.

3. An SSD module, comprising: a storage control chip, a Flash, and a lead frame;
wherein the lead frame comprises: a first base island, configured to mount the storage control chip;
a second base island, configured to mount the Flash; and a pin array, distributed around a periphery of the first base island;
wherein the storage control chip is arranged on the first base island, and the Flash is arranged on the second base island; solder pads of the storage control chip, solder pads of the flash, and the pin array are wire bonded by means of bonding wires and packaged into a QFN package to form the SSD module.

4. The SSD module according to claim 3, wherein at least one of the solder pads of the storage control chip, which is wire bonded to the Flash, is located on a side of the power pin; at least one of the solder pads of the Flash, which is wire bonded to the storage control chip, is located on another side of the power pin.

5. The SSD module according to claim 4, wherein the storage control chip is arranged with a strobe module, and the strobe module is configured to adjust signal types of the solder pads of the storage control chip, enabling the signal types of the storage control chip to match signal types of the solder pads of the Flash.

6. The SSD module according to claim 5, wherein the strobe module comprises a control unit and a plurality of channel selection units; a control terminal of the control unit is connected to the plurality of channel selection units; each channel selection unit comprises a multiplexer and a plurality of I/O channels, an input end of the multiplexer being connected to a corresponding I/O port of the storage control chip; the multiplexer is configured to receive a signal from the control unit, and a selection terminal of the multiplexer is caused to be connected to an end of one of the plurality of I/O channels; another end of each I/O channel is connected to a corresponding solder pad of the storage control chip.

7. The SSD module according to claim 6, wherein the Flash comprises a plurality of Flashes; the plurality of Flashes are stacked and distributed in a staggered manner to form a stepped storage unit structure, and the solder pads, of a same type, of the plurality of Flashes are connected by bonding wires.

8. The SSD module according to claim 7, wherein both ends of the power pin are not covered by a colloid.

9. An SSD device, comprising: a PCB, peripheral components, a housing, and an SSD module;
wherein the peripheral components and the SSD module are arranged together on the PCB, and the PCB is arranged in the housing;
wherein the SSD module comprises: a storage control chip, a Flash, and a lead frame;
wherein the lead frame comprises: a first base island, configured to mount the storage control chip;
a second base island, configured to mount the Flash; and a pin array, distributed around a periphery of the first base island;
wherein the storage control chip is arranged on the first base island, and the Flash is arranged on the second base island; solder pads of the storage control chip, solder pads of the flash, and the pin array are wire bonded by means of bonding wires and packaged into a QFN package to form the SSD module.

10. The SSD device according to claim 9, wherein the PCB is arranged with gold fingers.
